(19) United States
(12) Patent Application Publication
(10) Pub. No.: US 2002/0030276 A1
(43) Pub. Date: Mar. 14, 2002

(54) Dimple array interconnect technique for semiconductor device

(76) Inventors: Guo-Quan Lu, Blacksburg, VA (US); Simon Sihua Wen, Blacksburg, VA (US)

Correspondence Address: McGuireWoods, LLP, Suite 1800, 1750 Tysons Blvd., McLean, VA, 22102-4215, US

(21) Appl. No.: 09/829,941

(22) Filed: Apr. 11, 2001

Related U.S. Application Data
(60) Provisional application No. 60/200,007, filed on Apr. 27, 2000.

(51) Int. Cl. H01L 29/40; H01L 23/52; H01L 23/48

(52) U.S. Cl. 257/758

(57) ABSTRACT

A conductive layer having a plurality dimples is provided for interconnecting a power device chip and a driver circuit for driving and controlling the power device chip within a power module. A plurality of concave-shaped dimples of the conductive layer form an electrical contact with the power device chip, and at least one convex-shaped dimple of the conductive layer forms an electrical contact with the driver circuit. Optionally, a group of through-holes are formed around each of the dimples.

### CROSS REFERENCE TO RELATED APPLICATIONS

This application claims priority to U.S. Provisional Application Ser. No. 60/200,007, filed on Apr. 27, 2000, the entire contents of which are herein incorporated by reference.

### GOVERNMENT INTERESTS

This invention was made with the United State Government support under government contract number 208-11-110F-104-352884-1 from the Office of Naval Research. The Government of the United States of America may have certain rights in the invention.

### DESCRIPTION

### BACKGROUND OF THE INVENTION

1. Field of the Invention

The present invention generally relates to power modules, more particularly to a power module which includes power devices and a driver circuit for controlling and driving the power device, and the interconnection therebetween.

2. Description of the Prior Art

A power module containing, as the integral parts, both power device chips and a driving circuit for driving and controlling the power device has been widely used as a power conversion unit for controlling peripheral equipment because of its small size and excellent workability.

Wire bonding technology has been widely used in today's power module and devices for interconnecting power device chips to driver circuits and to the output leads. However, for high-voltage, high-current applications, wire bonding technology has a number of reliability concerns.

For example, due to the limited heat dissipation of wire bonding modules, the heat generated by the power devices causes malfunction or even breakdown of the module. Also, when the wires are bonded to the terminals of the power device or driver circuit, the wire bonding apparatus may apply harmful impact on the input/output terminals which causes micro cracks in the silicon chips, thereby resulting in degradation of the device reliability. Furthermore, since, in wire bonding processing, multiple wires are bonded one after another, it is time-consuming and labor-intensive. Automated wire-bonder requires more complex monitoring systems and other expensive device, which increases manufacturing cost.

There is a need for simplified, efficient and production worthy methodology for interconnecting power devices with a driver circuit to form a power module.

### SUMMARY OF THE INVENTION

An advantage of the present invention is a simplified and more reliable interconnection structure for a power module having a power device chip and a driver circuit for driving and controlling the power device chip. Another advantage of the present invention is a simplified and cost-effective methodology for interconnecting a power device chip and a driving circuit for driving and controlling the power chip.

Additional advantages and other features of the present invention will be set forth in part in the description which follows and will become apparent to those having ordinary skill in the art upon examination of the following or may be learned from the practice of the present invention. The objects and advantages of the present invention may be realized and obtained as particularly pointed out in the appended claims.

According to the present invention, the foregoing and other advantages are achieved in part by a method for manufacturing an electrical component comprising the steps of forming at least one first dimple on a conductive layer, in which the first dimple is formed extending from a first main surface of said conductive layer. Subsequently, the first dimple is electrically connected to at least one terminal of a first semiconductor device formed on a first main surface thereof, so that said conductive layer forms electrical contact with said first semiconductor device.

Hence, according to the present invention, instead of wire bonding, a conductive layer having at least one dimple is electrically connected to a power chip device to provide an electrical contact with a driver circuit. Such conductive layer can be formed by simply stamping the conductive layer, thereby simplifying the interconnection process and reducing the manufacturing cost and time.

Another aspect of the present invention is an electrical component comprising a first semiconductor device having at least one first terminal on a first surface thereof, and a conductive layer having at least one first dimple extending from a first surface thereof, in which the first dimple is in electrical contact with the first terminal of the first semiconductor device.

Thus, according to the present invention, instead of wires, a conductive layer having at least one dimple is provided as a conductive path and, at the same time, a controllable standoff height, a heat dissipation path, thereby improving heat dissipation and reducing parasitic resistance and malfunction of the circuit.

Additional advantages of the present invention will become readily apparent to those skilled in this art from the following detailed description, wherein only the preferred embodiment of the present invention is shown and described, simply by way of illustration of the best mode contemplated for carrying out the present invention. As will be realized, the present invention is capable of other and different embodiments and its several details are capable of modifications in various obvious respects, all without departing from the present invention. Accordingly, the drawings and description are to be regarded as illustrative in nature, and not restrictive.

### BRIEF DESCRIPTION OF DRAWINGS

The foregoing and other advantages and aspects will be better understood from the following detailed description of a preferred embodiment of the invention with reference to the drawings, in which:

FIG. 1A is a top view of a conductive layer having a plurality of dimples according to the present invention;

FIG. 1B is a top view of the conductive layer of FIG. 1A, in which a plurality of groups of through-holes are formed on the conductive layer about each of the dimples;

FIG. 1C is a top view of the conductive layer of FIG. 1A, in which a plurality of through-holes are formed on the spaces between the dimples of the conductive layer;

FIG. 2 is a cross-sectional view taken along line X-Y of FIG. 1A;

FIG. 3A depicts a cross-section of a portion of an electric component, in which a power device chip is formed on and electrically connected to a substrate, in accordance with a certain embodiment of the present invention;

FIG. 3B depicts the electrical component of FIG. 3A, after a conductive layer is formed on and electrically connected the power device chip, in accordance with a certain embodiment of the present invention;

FIG. 3C depicts the electrical component of FIG. 3B, after an underfill material is formed in the space between the power device chip and the conductive layer, in accordance with a certain embodiment of the present invention; and

FIG. 3D depicts the electrical component fo FIG. 3C, after a driver circuit is formed on and electrically connected to the conductive layer, in accordance with a certain embodiment of the present invention.

### DETAILED DESCRIPTION OF A PREFERRED EMBODIMENT OF THE INVENTION

The present invention enables a simplified and reliable electrical component interconnection structure and a method for manufacturing the same by using a conductive layer having at least one dimple formed thereon, instead of wire bonding, to form an interconnection between power devices and a driver circuit for driving and controlling the power chip device.

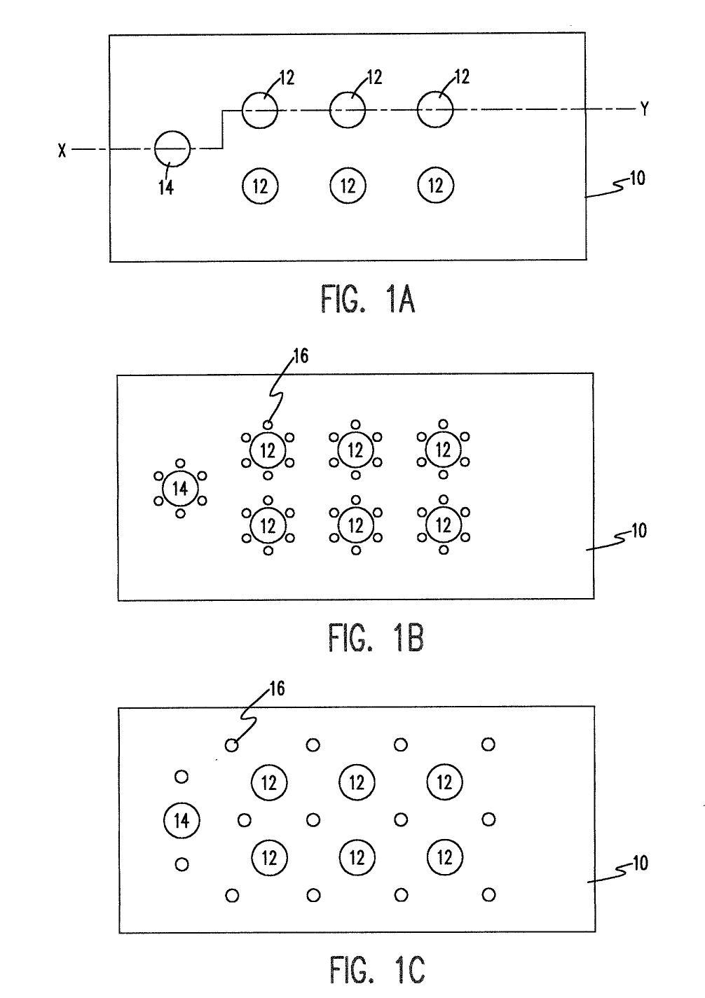

Referring now to the drawings, and more particularly to FIG. 1A, there is shown a top view of a conductive layer 10, according to the present invention, provided with a plurality of concave-shaped dimples 12 and a convex-shaped dimple 14. The material for the conductive layer 10 can be selected from a variety of metals (i.e., copper, aluminum, or nickel), metal alloys (i.e., copper alloy, aluminum alloy, or nickel alloy), or metal/insulator laminate materials (i.e., copper/polymer laminate, aluminum/polymer laminate, or nickel/polymer laminate). For example, according to a certain embodiment of the present invention, low cost materials, such as copper sheets can be used for the conductive layer 10, which provides excellent electric and thermal conductivity, compared to aluminum, the most commonly used material for wire bonding. The concave-shaped and convex-shaped dimples can be formed using a stamping machine which imposes the shape of the dimples into the conductive layer 10. The conductive layer 10 of this invention should be of sufficient rigidify to retain the dimple deformation therein after stamping. This can vary widely depending on the application. The chief requirement is to have a conductive layer 10, wherein at least one dimple can be impressed within the region inside the periphery of the layer, and the dimple can then be connected to a semiconductor device.

According to a certain embodiment of the present invention, as depicted in FIGS. 1B and 1C, the conductive layer 10 may be provided with a plurality of through-holes 16 in order to reduce the physical impact applied to the electrodes or terminals of a power device chip and a driver circuit during the assembly process, which will be described later in detail. FIG. 1B depicts a plurality of groups of through-holes 16 are formed in the conductive layer 10, and each group of the though-holes 16 is preferrably arranged to surround the dimples 12 and 14. As depicted in FIG. 1C, the through-holes 16 may be arranged on the spaces between the dimples 12 and 14 of the conductive layer 10.

The though-holes 16 are preferably made at the same time as the dimples 12 and 14 with the same staple machine. The through-holes 16 can assist in weakening the metal to allow for more flexibility of the conductive layer 10. Furthermore, the through-holes 16 can assist in preventing impact damage.

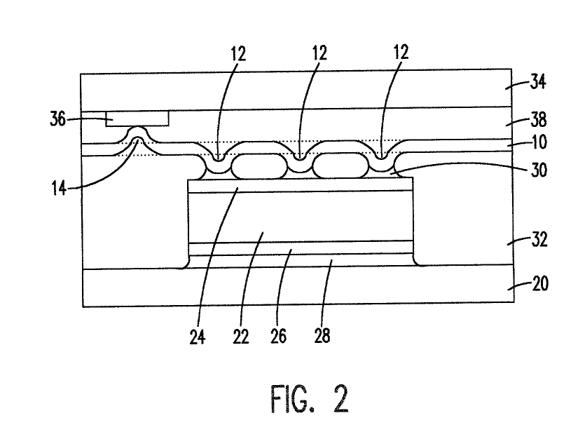

FIG. 2 depicts a portion of a power module according to the present invention, in which the conductive layer 10 of FIG. 1 is incorporated thereto to provide a conductive path between a power device chip 22 and a driver circuit 34 for driving and controlling the power device chip 22.

A power device chip 22 is preferably mounted on the substrate 20, e.g., a direct bonding copper (DBC) substrate by using conventional solder bonding technique. The power chip 22 can be any kind of conventional power devices having at least one electrode or input/output terminal on its surface, e.g., a power transistor chip, an MOSFET chip, a diode chip, a thyristor chip on an IGBT chip or the like. For example, the power chip 22 shown in FIG. 2 is a diode chip having two electrodes, an anode 24 on its upper surface and a cathode 26 formed on the lower surfaces of the diode chip 22. The power device chip 22 is preferably in an electrical contact with the substrate 20 via the cathode 26 and solder bonding 28.

FIG. 2 further shows the conductive layer 10 mounted on the power device chip 22. The conductive layer has a plurality of concave-shaped dimples 12 extending from the lower surface to form an electrical contact with the diode chip 22 via solder bonding 32 and the anode 24 of the power device chip 22. A underfill material 24 may also be provided to fill the space between the conductive layer 10 and the diode chip 22 and the space between the conductive layer 10 and the substrate 20.

The conductive layer 22 also preferably has at least one convex-shaped dimple 34 extending from the upper surface to form an electrical contact with the driver circuit 24 via a terminal 36 of the driver circuit 34. The space between the driver circuit 34 and the conductive layer 10 may also be filled by a polymer layer 38.

Hence, according to the present invention, the conductive layer 10 with a plurality of dimples 12 and 14 enables a multi-layered power chip module, in which the power device chip 22 and the driver circuit 34 are stacked on the same portion of the substrate 20, thereby reducing the length of the conductive path therebetween. Thus, the present invention reduces the component size and the parasitic capacitance, as compared to the wire bonding technology, in which a power device chip and its driver circuit are arranged on the different portions of the substrate, and a relatively longer conductive path is formed therebetween via wires. Also, by adjusting the height of the dimples 12 and 14, the power module can be optimized to facilitate the noise control

In addition, the heat generated from the power device chip 22 is also dissipated via the conductive layer 10, and, therefore, the heat transferred from the power device chip 22 to the driver circuit 34 is significantly reduced. Therefore, the present invention reduces malfunction of the driver circuit 34, and increases the long-term reliability. Also, because the amount of the heat transferred to the driver circuit 34 is significantly reduced, the power module can be designed to handle higher power density.

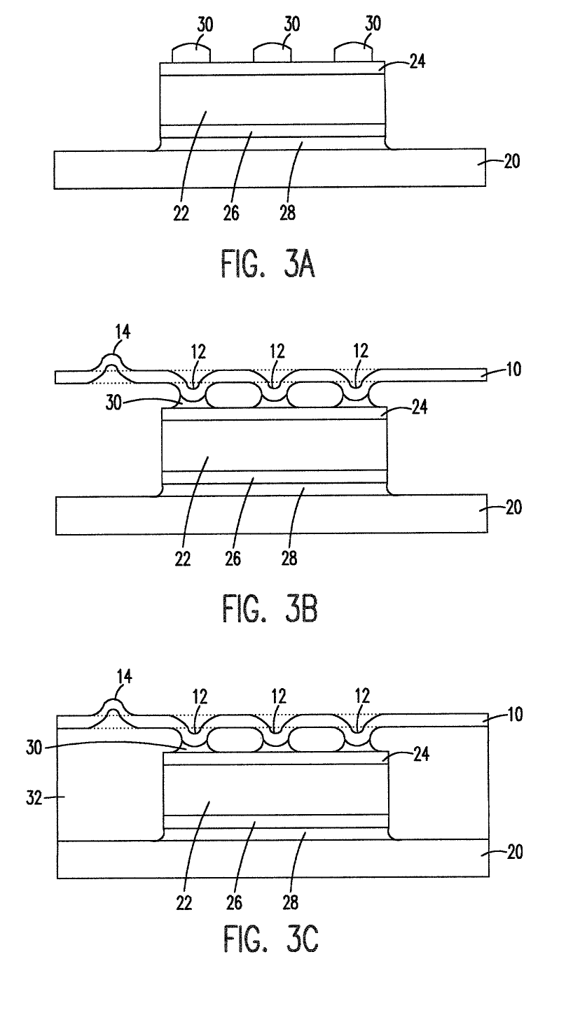

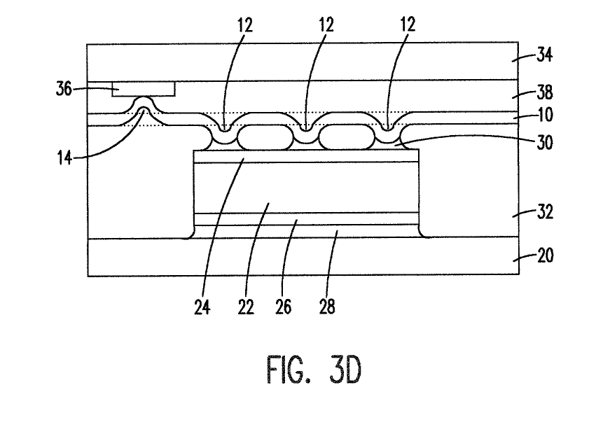

FIGS. 3A-3D depict the process for manufacturing a power module such as shown in FIG. 2 according to the present invention. In FIG. 3A, there is shown a power device chip 22, e.g., a diode chip, having an anode 24 on its upper surface and a cathode on its lower surface, mounted on and electrically connected to a substrate 20 via the cathode 26 and solder bonding 28. Solder bumps 30 are formed on the surface of an anode 24 of the power device chip 22. The locations of the dimples 12 and 14 on the conductive layer correspond to the locations of the bumps on the power device chip 22. Thus, a variety of power device chips can be accommodated using this invention simply by selecting an appropriate stamp pattern.

In FIG. 3B, a conductive layer 10 is prepared to have a plurality of concave-shaped dimples 12 extending from the lower surface of the conductive layer 10 to the direction substantially perpendicular to the conductive layer 10. The conductive layer 10 is further provided with at least one convex-shaped dimple 14 extending from the upper surface of the conductive layer 10 to the direction substantially perpendicular to the conductive layer 10, and substantially orthogonal to the direction to which the concave-shaped dimples 12 are extending.

The concave-shaped dimples 12 and convex-shaped dimple 14 can be easily formed by a simple punching process. For example, the location and height of each dimple can be predetermined depending on the characteristics of a power device chip and a driver chip to optimize the parasitic noise. Contrarily, conventional wire bonding requires a complex and expensive wire bonding apparatus, which is very often equipped with a CCD camera to monitor each bonding process. Also, wire bonding is time-consuming because wires are bonded to device pads one by one. According to the present invention, however, all dimples can be attached simultaneously to the device by a single solder flow process. Thus, the present invention significantly reduces the manufacturing cost and time.

As shown in FIG. 3B, the conductive layer 10 is mounted on the power device chip 22 so that the concave-shaped dimples 12 are mounted on the solder bumps 24. Subsequently, a conventional solder bumping process is performed to form an electrical contact between the conductive layer 10 and the power device chip 22. As previously described, it has been known that an excessive impact is applied to the terminals or electrodes of the power chip device when the tip of a wire is brought to the terminals or electrodes by an automated wire bonding apparatus. According to the present invention, this problem is solved by using conventional solder bumping process, which significantly reduces the impact on the terminals or electrodes of the power chip device while ensuring a solid electrical and mechanical interconnection therebetween. In the case that aluminum is used for the conductive layer 10, the bonding process can be performed by conventional ultrasonic bonding technique, which does not require solder.

Also, as shown in FIG. 1B, by forming a group of through-holes 16 around the each dimples 12 and 14, any impact such as, for example, thermal and mechanical stresses during the device service life, applied to the terminal of the terminal of the power device chip can be even more reduced.

As shown in FIG. 3C, the space between the conductive layer 10 and the power device chip 22, and the space between the conductive layer 10 and the substrate 20 are preferably filled with a heat dissipating and mechanical support material. Subsequently, as shown in FIG. 3D, a driver circuit 34 is mounted on the conductive layer 10 with polymer 38 therebetween so that a terminal 36 of the driver circuit 34 is in an electrical contact with the convex-shaped dimple 14. Thus, according to the present invention, by using the conductive layer 10 with the dimples 12 and 14, the power device chip 22 and the driver circuit 34 can be easily stacked on the same portion of the substrate 20, thereby reducing the device size. The driver circuit 34 can be on any substrate of interest including flex-circuits and semiconductor substrates, and its form is selected for the application to be achieved. Examples of driver circuits are a controller chip, a microprocessor chip, a circuit layer, or circuit board with components thereon.

As can be seen from the above description, the present invention provides a simplified, cost-effective, reliable and production-worthy power module interconnection structure and the method thereof. Particularly, the present invention has numerous advantages over conventional wire bonding technique.

While the invention has been described in terms of a single preferred embodiment, those skilled in the art will recognize that the invention can be practiced with modification within the spirit and scope of the appended claims.

We claim:

1. An electrical component comprising:
a first semiconductor device having at least one first terminal on a first surface thereof; and
a conductive layer having at least one first dimple extending from a first surface thereof, said first dimple being in electrical contact with said first terminal of said first semiconductor device.

2. The electrical component of claim 1, wherein said conductive layer has at least one second dimple extending from a second surface thereof.

3. The electrical component of claim 2, further comprising a second semiconductor device having at least one second terminal, said second terminal being in electrical contact with said second dimple of said conductive layer.

4. The electrical component of claim 2, wherein said first dimple extends toward substantially a first perpendicular direction to said conductive layer, and said second dimple is extending toward substantially a second perpendicular direction to said conductive layer.

5. The electrical component of claim 1, wherein said conductive layer is selected from the group consisting of a metal, a metal alloy, and a metal/insulator laminate material.

6. The electrical component of claim 1, wherein said conductive layer is selected from the group consisting of copper, aluminum, nickel, a copper alloy, an aluminum alloy, a nickel alloy, a copper/polymer laminate, an aluminum/polymer laminate, and a nickel/polymer laminate.

7. The electrical component of claim 1, wherein said conductive layer further comprising a plurality of through-holes formed thereon, said through-holes arranged surrounding said first dimples or evenly distributed on said conductively layer.

8. The electrical component of claim 3, wherein said first semiconductor device is a power device and said second semiconductor device is a driving circuit for driving and controlling said power device.

9. The electrical component of claim 8, further comprising a substrate being in electrical contact with a second terminal on a second surface of said first semiconductor device.

10. The electrical component of claim 1, wherein said conductive layer includes a plurality of dimples, each of said first dimples electrically contacting said first semiconductor device.

11. The electrical component of claim 3, wherein said first and second semiconductor devices are aligned linearly with said conductive layer therebetween.

12. A method for manufacturing an electrical component, the method comprising the steps of:
forming at least one first dimple on a conductive layer, said first dimple extending from a first main surface of said conductive layer; and
electrically connecting said first dimple to at least one terminal of a first semiconductor device formed on a first main surface thereof, so that said conductive layer forms electrical contact with said first semiconductor device.

13. The method of claim 12, further comprising the steps of:
forming at least one second dimple on said conductive layer, said second dimple extending from a second main surface of said conductive layer; and
electrically connecting said second dimple to at least one terminal of a second semiconductor device, so that said conductive layer forms electrical contact with said second semiconductor device.

14. The method of claim 13, further comprising the steps of electrically connecting a substrate to a second terminal of said first semiconductor device formed on a second main surface thereof.

15. The method of claim 13, wherein said first forming step forms said first dimple to extend toward substantially a first perpendicular direction to said conductive layer, and said second forming step forms said second dimple to extend toward substantially a second perpendicular direction to said conductive layer.

16. The method of claim 13, further comprising the step of forming a plurality of through-holes.

17. The method of claim 12, further comprising the step of filling a space between said first semiconductor device and said conductive layer with a heat dissipation material.

18. The method of claim 13, further comprising the step of filling a space between said conductive layer and said second semiconductor device with polymer.

19. The method of claim 13, wherein said first and second dimples are electrically connected by solder bonding or ultrasonic bonding.
